(19) United States
(12) Patent Application Publication
(10) Pub. No.: US 2025/0133839 A1
(43) Pub. Date: Apr. 24, 2025

(54) PIXEL AND IMAGE SENSOR INCLUDING THE SAME

(71) Applicant: SAMSUNG ELECTRONICS CO., LTD., Suwon-si (KR)

(72) Inventor: Juntaek Lee, Suwon-si, Gyeonggi-do (KR)

(21) Appl. No.: 18/767,147

(22) Filed: Jul. 9, 2024

(30) Foreign Application Priority Data
Oct. 19, 2023 (KR) 10-2023-0140625

(51) Int. Cl. H01L 27/146

(52) U.S. Cl. CPC H10F 39/182; H10F 39/8027; H10F 39/8037; H10F 39/8053; H10F 39/8063

(57) ABSTRACT

An image sensor includes a plurality of pixels, wherein each of the plurality of pixels includes a first epitaxial layer disposed on a first surface of a semiconductor substrate and formed to have a first conductive type by an epitaxial growth process, a photoelectric conversion device disposed on the first epitaxial layer, the photoelectric conversion device having a second conductive type which differs from the first conductive type and a second epitaxial layer disposed between the photoelectric conversion device and a second surface of the semiconductor substrate and formed to have the second conductive type through the epitaxial growth process, wherein the photoelectric conversion device is an epitaxial layer of the second conductive type formed by the epitaxial growth process.

### CROSS-REFERENCE TO RELATED APPLICATION

This application is based on and claims priority to Korean Patent Application No. 10-2023-0140625, filed in the Korean Intellectual Property Office, on Oct. 19, 2023, the disclosure of which is incorporated by reference herein in its entirety.

### BACKGROUND

Image sensors are devices that capture a two-dimensional (2D) or three-dimensional (3D) image of an object. Image sensors generate an image of an object by using a photoelectric conversion device which reacts based on the strength of light reflected from the object. As the computer industry and the communication industry advance, the demand for image sensors having enhanced performance is increasing in various electronic devices, such as digital cameras, camcorders, personal communication systems (PCSs), game machines, security cameras, medical micro-cameras, and portable phones.

Image sensors may include a pixel, and the pixel may include a photoelectric conversion device that generates a photocharge from light. In forming a photoelectric conversion device, impurities having a conductive type, which differs from that of a substrate, may be implanted into the substrate by an ion implantation process. As impurities are implanted, a lattice defect of the substrate may occur, causing noise of image data.

### SUMMARY

In general, in some aspects, the present disclosure is directed toward a pixel and an image sensor including the pixel, in which a photoelectric conversion device of a second conductive type is formed on a first epitaxial layer having a first conductive type by using an epitaxial growth process, and thus, a lattice defect is reduced and noise of image data is reduced.

In general, according to some aspects, an image sensor includes a plurality of pixels, wherein each of the plurality of pixels includes a first epitaxial layer disposed on a first surface of a semiconductor substrate and formed to have a first conductive type by an epitaxial growth process, a photoelectric conversion device disposed on the first epitaxial layer, the photoelectric conversion device having a second conductive type which differs from the first conductive type and a second epitaxial layer disposed between the photoelectric conversion device and a second surface of the semiconductor substrate and formed to have the second conductive type through the epitaxial growth process, wherein the photoelectric conversion device is an epitaxial layer of the second conductive type formed by the epitaxial growth process.

According to some aspects of the present disclosure, a pixel includes a semiconductor substrate including a first surface and a second surface, a vertical transmission gate formed on the second surface of the semiconductor substrate, and a floating diffusion region configured to accumulate a photocharge generated from the semiconductor substrate through the vertical transmission gate, wherein the semiconductor substrate includes a first epitaxial layer having a first conductive type disposed on the first surface of the semiconductor substrate, a photoelectric conversion device formed by an epitaxial growth process in a direction toward the second surface of the semiconductor substrate from the first surface of the semiconductor substrate to contact the first epitaxial layer, the photoelectric conversion device having a second conductive type which differs from the first conductive type, and a second epitaxial layer contacting the photoelectric conversion device in a direction toward the second surface of the semiconductor substrate from the first surface of the semiconductor substrate, the second epitaxial layer having the second conductive type.

According to some aspects of the present disclosure, an image sensor includes a color filter disposed on a first surface of a semiconductor substrate in a second direction opposite to a first direction toward a second surface of the semiconductor substrate from the first surface of the semiconductor substrate, a lens layer disposed on the color filter in the second direction, a first epitaxial layer disposed between the first surface and the second surface of the semiconductor substrate and arranged in the first direction on the first surface of the semiconductor substrate, the first epitaxial layer having a first conductive type, a photoelectric conversion device disposed on the first epitaxial layer in the first direction, the photoelectric conversion device being an epitaxial layer having a second conductive type, and a second epitaxial layer disposed between the first surface and the second surface of the semiconductor substrate and arranged in the second direction on the second surface of the semiconductor substrate, the second epitaxial layer having a third conductive type.

### BRIEF DESCRIPTION OF THE DRAWINGS

Example implementations will be more clearly understood from the following detailed description, taken in conjunction with the accompanying drawings.

FIG. 1 is a block diagram illustrating an example of an image sensor according to some implementations.

FIG. 2 is a circuit diagram of an examples of a pixel included in an image sensor, according to some implementations.

FIG. 3 is a cross-sectional view schematically illustrating an example of a pixel according to some implementations.

FIG. 4 is a cross-sectional view illustrating an example of a pixel of an image sensor according to some implementations.

FIG. 5 is a diagram for describing an example of a device isolation layer according to some implementations.

FIG. 6A is a cross-sectional view of an example of a pixel for describing a method of implanting impurities into a photoelectric conversion device according to some implementations.

FIG. 6B is a cross-sectional view of an example of a pixel for describing a method of implanting impurities into a photoelectric conversion device according to some implementations.

FIG. 7A is a cross-sectional view of an example of a pixel for describing a second epitaxial layer and a photoelectric conversion device according to some implementations.

FIG. 7B is a cross-sectional view of an example of a pixel illustrating a second epitaxial layer into which impurities are implanted according to some implementations.

FIG. 8 is a cross-sectional view of an example of a pixel illustrating a second epitaxial layer having a first conductive type according to some implementations.

FIG. 9 is a flowchart describing an example of a method of manufacturing an image sensor according to some implementations.

FIGS. 10A to 10F are cross-sectional views of an example of a pixel for describing a method of manufacturing an image sensor according to some implementations.

FIG. 11 is a cross-sectional view of an example of a pixel for describing a method of manufacturing an image sensor by using an ion implantation process, according to some implementations.

### DETAILED DESCRIPTION

Hereinafter, example implementations will be described in detail with reference to the accompanying drawings. Like reference numerals refer to like elements in the drawings, and their repeated descriptions may be omitted.

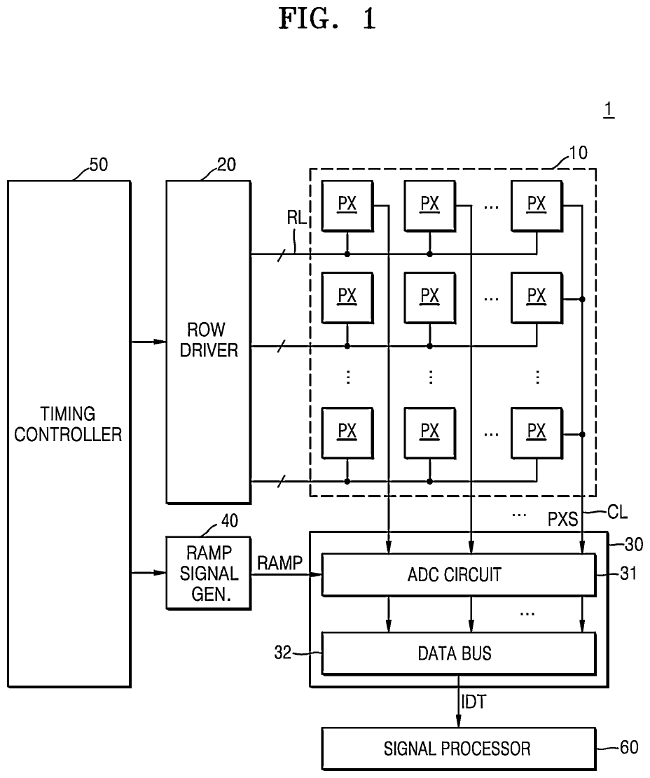

FIG. 1 is a block diagram illustrating an example of an image sensor according to some implementations. In FIG. 1, an image sensor 1 may be equipped in an electronic device having an image or light sensing function. For example, the image sensor 1 may be equipped in electronic devices such as cameras, smartphones, wearable devices, Internet of things (IoT) devices, tablet personal computers (PCs), personal digital assistants (PDAs), portable multimedia players (PMPs), and navigation devices. Also, the image sensor 1 may be equipped in an electronic device which is included as a part in vehicles, furniture, manufacturing facilities, doors, and various meters.

In FIG. 1, the image sensor 1 may include a pixel array 10, a row driver 20, a readout circuit 30, a ramp signal generator 40, a timing controller 50, and a signal processor 60, and the readout circuit 30 may include an analog-to-digital conversion (ADC) circuit 31 and a data bus 32.

The pixel array 10 may include a plurality of row lines RL, a plurality of column lines CL, and a plurality of pixels PX, which are connected with the plurality of row lines RL and the plurality of column lines CL and are arranged in a matrix form. In an embodiment, the plurality of pixels PX may each be an active pixel sensor (APS).

Each of the plurality of pixels PX may include at least one photoelectric conversion device, and each pixel PX may sense light by using the photoelectric conversion device and may output an image signal, which is an electrical signal based on the sensed light. For example, the photoelectric conversion device may be a photo sensing device, which includes an organic material or an inorganic material, such as an inorganic photodiode, an organic photodiode, a Perovskite photodiode, a phototransistor, a photogate, or a pinned photodiode. In an embodiment, each of the plurality of pixels PX may include a plurality of photoelectric conversion devices.

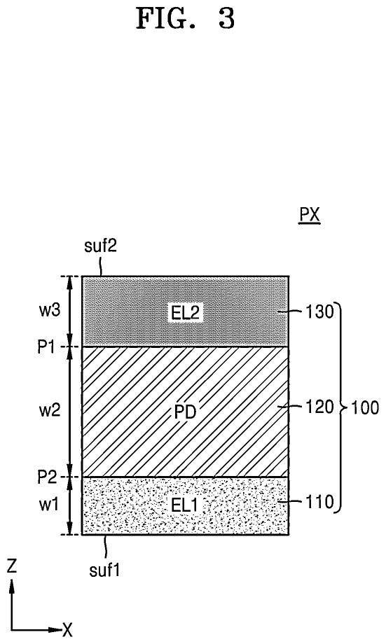

In some implementations, the photoelectric conversion device may be an epitaxial layer that is formed by an epitaxial growth process. The pixel PX may include a first epitaxial layer, a photoelectric device, and a second epitaxial layer. Each of the first epitaxial layer, the photoelectric conversion device, and the second epitaxial layer may be formed by an epitaxial growth process. The first epitaxial layer may be of a first conductive type, and the photoelectric conversion device may be of a second conductive type. For example, the pixel PX may include an N-type photoelectric conversion device formed on a P-type first epitaxial layer. A structure of the pixel PX will be described below in detail with reference to FIG. 3.

In some implementations, impurities of the second conductive type may be further implanted into a photoelectric conversion device of the second conductive type by using an ion implantation process. Impurities may be further implanted into a photoelectric conversion device which is an epitaxial layer having the second conductive type, based on an ion implantation process. For example, N-type impurities having a certain concentration may be implanted into a photoelectric conversion device which is an N-type epitaxial layer.

Impurities of the second conductive type may be further implanted into a photoelectric conversion device which is an epitaxial layer of the second conductive type, based on an ion implantation process, and thus, even when a relatively less amount of impurities of the second conductive type than the amount of impurities of the second conductive type implanted into an epitaxial layer of the first conductive type by an ion implantation process are implanted into an epitaxial layer having the first conductive type by using an ion implantation process, a photoelectric conversion device may be formed. Because impurities of the second conductive type are further implanted into a photoelectric conversion device which is an epitaxial layer of the second conductive type, a photoelectric conversion device may be generated at an appropriate impurity concentration of the second conductive type and a photoelectric effect of a photoelectric conversion device may be enhanced. Also, a relatively small amount of impurities of the second conductive type may be implanted by an ion implantation process, and thus, a lattice defect may be minimized.

Furthermore, a micro lens for light collection may be disposed on each of the plurality of pixels PX or on each of pixel groups each including adjacent pixels PX. Each of the plurality of pixels PX may sense light of a certain spectrum area from light received through the micro lens. For example, the pixel array 10 may include a red pixel which converts light of a red spectrum area into an electrical signal, a green pixel which converts light of a green spectrum area into an electrical signal, and a blue pixel which converts light of a blue spectrum area into an electrical signal. A color filter for transmitting light of a certain spectrum area may be disposed on each of the plurality of pixels PX. However, the pixel array 10 is not limited thereto, and the pixel array 10 may include pixels which convert light of a spectrum area, other than red, green, and blue, into an electrical signal.

A color filter array for transmitting light of a certain spectrum area may be disposed on the plurality of pixels PX, and a color capable of being sensed by a corresponding pixel may be determined based on a color filter disposed on each of the plurality of pixels PX. However, the present disclosure is not limited thereto, and in some implementations, a certain photoelectric conversion device may convert light of a certain wavelength band into an electrical signal based on a level of an electrical signal applied to the certain photoelectric conversion device. According to some implementations, the pixel PX may include two or more photoelectric conversion devices.

The row driver 20 may drive the pixel array 10 by row units. The row driver 20 may decode a row control signal (for example, an address signal) received from the timing controller 50 and may select at least one row line from among row lines configuring the pixel array 10 in response to the decoded row control signal. For example, the row driver 20 may generate a selection signal which selects one of a plurality of rows. Also, the pixel array 10 may output a pixel signal PXS from a row selected by the selection signal provided from the row driver 20.

The row driver 20 may transfer, to the pixel array 10, control signals for outputting the pixel signal PXS, and the pixel PX may operate in response to the control signals to output the pixel signal PXS.

The ramp signal generator 40 may generate a ramp signal RAMP which increases or decreases with a certain slope and may provide the ramp signal RAMP to the ADC circuit 31 of the readout circuit 30.

The readout circuit 30 may read out the pixel signal PXS from pixels PX of a row selected by the row driver 20 from among the plurality of pixels PX. Accordingly, the pixel signal PXS may include a reset signal or an image signal (or a sensing signal). The readout circuit 30 may convert reset signals and image signals, received from the pixel array 10 through a plurality of column lines CL, into digital signals to generate and output image data IDT, based on the ramp signal RAMP from the ramp signal generator 40.

The ADC circuit 31 may include at least one ADC. For example, the ADC circuit 31 may include a plurality of analog-to-digital converters (ADCs) respectively corresponding to the plurality of column lines, compare the ramp signal RAMP with each of the reset signal and the image signal each received through a corresponding column line CL, and generate a pixel value based on comparison results. For example, the ADC may remove the reset signal from the image signal and may generate a pixel value representing the amount of light sensed in the pixel PX. The image data IDT may include pixel values.

The image data IDT generated by the ADC circuit 31 may be output through the data bus 32. For example, the image data IDT may be provided to the signal processor 60.

The data bus 32 may temporarily store the image data IDT output from the ADC circuit 31 and may then output the stored image data IDT. The data bus 32 may include a plurality of column memories and a column decoder. The image data IDT stored in the column memory may be output to the signal processor 60 based on control by the column decoder.

The ADC circuit 31 may include a plurality of correlated double sampling (CDS) circuits and a plurality of counter circuits. The ADC circuit 31 may convert the pixel signal PXS, input from the pixel array 10, into a pixel value, which is a digital signal. Each of pixel signals PXS respectively received through the plurality of column lines CL may be converted into a pixel value, which is a digital signal, by the CDS circuit and the counter circuit.

The CDS circuit may compare the pixel signal PXS, received through the column line CL, with the ramp signal RAMP and may output a comparison result. When a level of the ramp signal RAMP is equal to that of the pixel signal PXS, the CDS circuit may output a comparison signal which is shifted from a first level (for example, logic high) to a second level (for example, low logic). A time at which a level of the comparison signal is shifted may be determined based on a level of the pixel signal PXS.

The CDS circuit may sample and hold the pixel signal PXS provided from the pixel PX, based on a CDS scheme, and may doubly sample a level based on an image signal and a level of certain noise (for example, a reset signal) to generate the comparison signal, based on a level corresponding to the difference thereof.

In an embodiment, the CDS circuit may include one or more comparators. Each of the comparators may be implemented as an operational transconductance amplifier (OTA) or a differential amplifier.

The signal processor 60 may receive the image data IDT from the readout circuit 30. The signal processor 60 may perform image processing on the image data IDT. For example, the signal processor 60 may perform noise reduction processing, gain adjustment, waveform normalization processing, interpolation processing, white balance processing, gamma processing, edge emphasis processing, and binning on a pixel value included in the image data IDT. In FIG. 1, the signal processor 60 is illustrated as being included in the image sensor 1, but is not limited thereto and according to embodiments, the signal processor 60 may be provided outside the image sensor 1. For example, the signal processor 60 may be included in an external processor of the image sensor 1.

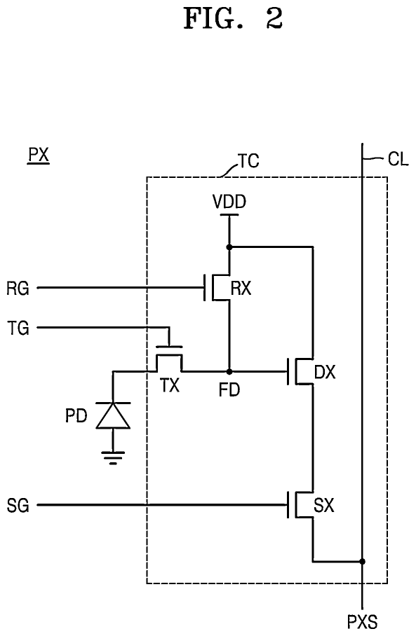

FIG. 2 is a circuit diagram of an examples of a pixel included in an image sensor, according to some implementations. In FIG. 2, a pixel PX may represent one of the pixels PX included in the pixel array 10 of FIG. 1.

In FIG. 2, the pixel PX may include a photodiode PD and a transmission circuit TC. The photodiode PD may be replaced with another photo sensing device. The photodiode PD may be referred to as a photoelectric conversion device. The transmission circuit TC may include a reset transistor RX, a transmission transistor TX, a driving transistor DX, and a selection transistor SX. However, a structure of the transmission circuit TC is not limited thereto, and a structure of the transmission circuit TC may vary. The reset transistor RX may include a reset gate RG, the selection transistor SX may include a selection gate SG, and the transmission transistor TX may include a transmission gate TG.

The photodiode PD may generate a photocharge which varies, based on the strength of incident light. The transmission circuit TC may generate an analog pixel signal PXS corresponding to internal reset noise or the photodiode PD.

The transmission circuit TC may operate based on received control signals. The transmission transistor TX may transfer the photocharge from the photodiode PD to a floating diffusion region FD based on a transmission control signal.

The driving transistor DX may amplify the photocharge based on an electrical potential based on photocharges accumulated in the floating diffusion region FD and may output the amplified photocharge through the selection transistor SX. When the selection transistor SX is turned on in response to a selection control signal, a sensing signal (i.e., a light sensing signal) corresponding to a voltage level of the floating diffusion region FD may be output as, for example, the pixel signal PXS.

Additionally, the reset transistor RX may reset the floating diffusion region FD with a source voltage VDD based on a reset control signal. At this time, a reset signal corresponding to a voltage level of the floating diffusion region FD may be output as the pixel signal PXS.

The pixel signal PXS may be output as a readout circuit (for example, the readout circuit 30 of FIG. 1) through the column line CL.

FIG. 3 is a cross-sectional view schematically illustrating an example of a pixel according to some implementations. In FIG. 3, a pixel PX of an image sensor (for example, the image sensor 1 of FIG. 1) is shown and illustrates a semiconductor substrate 100 of the pixel PX.

In FIG. 3, the pixel PX may include the semiconductor substrate 100. The semiconductor substrate 100 may include a first surface suf1 and a second surface suf2 opposite to the first surface suf1. For convenience, a surface of a first epitaxial layer 110 may be referred to as the first surface suf1, and a surface of a second epitaxial layer 130 may be referred to as the second surface suf2.

The semiconductor substrate 100 may include the first epitaxial layer 110, a photoelectric conversion device 120, and the second epitaxial layer 130. The first epitaxial layer 110 may be disposed on the first surface suf1 of the semiconductor substrate 100. The first epitaxial layer 110 may be arranged in a first direction Z on the first surface suf1.

The first epitaxial layer 110 may be an epitaxial layer of a first conductive type formed by an epitaxial growth process. For example, the first conductive type may be P type. The first epitaxial layer 110 may be a P-type epitaxial layer. A P-type first epitaxial layer 110 may be formed on a silicon bulk.

The photoelectric conversion device 120 may be disposed on the semiconductor substrate 100. The photoelectric conversion device 120 may be a photodiode region. The photoelectric conversion device 120 may generate a photocharge based on light incident on the pixel PX. An electron-hole pair may be generated in response to the incident light, and the photoelectric conversion device 120 may collect the electrons or holes. The photoelectric conversion device 120 may be disposed on the first epitaxial layer 110. The photoelectric conversion device 120 may be disposed in a first direction on the first epitaxial layer 110.

In some implementations, the photoelectric conversion device 120 may be an epitaxial layer formed by an epitaxial growth process. The photoelectric conversion device 120 may be formed as a second conductive type by an epitaxial growth process. For example, the photoelectric conversion device 120 may be a depletion region. The second conductive type may differ from the first conductive type. For example, the first conductive type may be P type and the second conductive type may be N type. By adjusting impurities (dopant) and/or a doping concentration in an epitaxial growth process, the photoelectric conversion device 120 may be formed as a certain conductive type to have a certain doping concentration. In the first epitaxial layer 110 grown as a P type, an N-type photoelectric conversion device 120 may be formed by an epitaxial growth process.

The second epitaxial layer 130 may be disposed on the semiconductor substrate 100. The second epitaxial layer 130 may be disposed on the photoelectric conversion device 120. The second epitaxial layer 130 may be disposed in a first direction Z on the photoelectric conversion device 120. The second epitaxial layer 130 may be disposed between the photoelectric conversion device 120 and the second surface suf2.

In some implementations, the second epitaxial layer 130 may be an epitaxial layer formed by an epitaxial growth process. For example, the second epitaxial layer 130 may be formed as the same conductive type as that of the photoelectric conversion device 120 by an epitaxial growth process. The second epitaxial layer 130 may be formed as the second conductive type. For example, the second epitaxial layer 130 may be N type. However, the inventive concept is not limited thereto, and the second epitaxial layer 130 may be formed as the same conductive type as that of the photoelectric conversion device 120.

The photoelectric conversion device 120 may be formed as the second conductive type to have a first concentration by using an epitaxial growth process. The second epitaxial layer 130 may be formed as the second conductive type to have a second concentration by using an epitaxial growth process. For example, the photoelectric conversion device 120 may be formed as an epitaxial layer having the first concentration by using an epitaxial growth process, and the second epitaxial layer 130 may be formed as an epitaxial layer having the second concentration. In an embodiment, the first concentration may differ from the second concentration. When performing an epitaxial growth process, because the first concentration differs from the second concentration, the photoelectric conversion device 120 may be differentiated from the second epitaxial layer 130. For example, the photoelectric conversion device 120 may be formed with the first concentration up to a first portion p1 of the semiconductor substrate 100 from a second portion p2 of the semiconductor substrate 100, and the second epitaxial layer 130 may be formed with the second concentration up to the second surface suf2 from the first portion p1 of the semiconductor substrate 100.

In some implementations, the first concentration may be higher than the second concentration. An impurity concentration of the second conductive type of the photoelectric conversion device 120 may be higher than an impurity concentration of the second conductive type of the second epitaxial layer 130. For example, based on an epitaxial growth process, the photoelectric conversion device 120 may be formed to have N-type impurities of a relatively high concentration, and the second epitaxial layer 130 may be formed to have N-type impurities of a relatively low concentration.

In the semiconductor substrate 100, sizes of at least two of the first epitaxial layer 110, the photoelectric conversion device 120, and the second epitaxial layer 130 may differ. A size of the first epitaxial layer 110 may denote a length of a region, occupied by the first epitaxial layer 110, of the semiconductor substrate 100 in a Z-axis direction. A size of the photoelectric conversion device 120 may denote a length of a region, occupied by the photoelectric conversion device 120, of the semiconductor substrate 100 in the Z-axis direction. A size of the second epitaxial layer 130 may denote a length of a region, occupied by the second epitaxial layer 130, of the semiconductor substrate 100 in the Z-axis direction.

A size of the first epitaxial layer 110 may differ from that of the photoelectric conversion device 120. For example, a size of the first epitaxial layer 110 may be less than that of the photoelectric conversion device 120. For example, a size of the first epitaxial layer 110 may correspond to a first length w1, and a size of the photoelectric conversion device 120 may correspond to a second length w2. The first length w1 may be less than the second length w2, and thus, a size of the first epitaxial layer 110 may be less than that of the photoelectric conversion device 120.

A size of the first epitaxial layer 110 may differ from that of the second epitaxial layer 130. For example, a size of the first epitaxial layer 110 may correspond to the first length w1, and a size of the second epitaxial layer 130 may correspond to a third length w3. The first length w1 may be less than the third length w3, and thus, a size of the first epitaxial layer 110 may be less than that of the second epitaxial layer 130. For example, in the semiconductor substrate 100, a size occupied by the first epitaxial layer 110 may be about 20%, and a size occupied by the photoelectric conversion device 120 and the second epitaxial layer 130 may be about 80%. However, numerical values of the sizes described above may be an embodiment and are not limited thereto.

The pixel PX according to an embodiment may include a photoelectric conversion device of the second conductive type formed on a first epitaxial layer of the first conductive type by an epitaxial growth process, and thus, a lattice defect of the semiconductor substrate 100 may be minimized. Accordingly, the occurrence of a dark current caused by the occurrence of a free charge may be minimized, and noise in image data may be minimized, thereby enhancing the image quality of an image sensor.

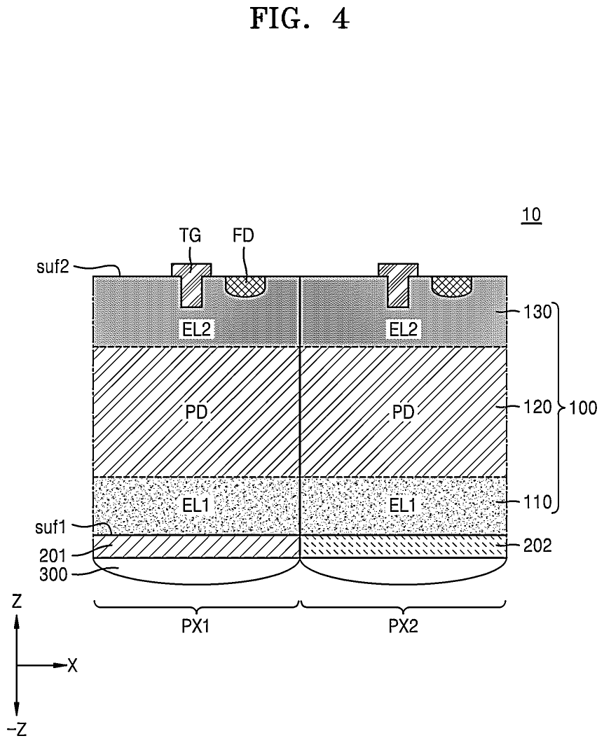

FIG. 4 is a cross-sectional view illustrating an example of a pixel of an image sensor according to some implementations. In FIG. 4, at least a portion of a pixel array 10 is shown in which a first pixel PX1 and a second pixel PX2 of pixels are included in the pixel array 10. The second pixel PX2 may be a pixel adjacent to the first pixel PX1. The pixel PX of FIG. 3 may be applied to the first pixel PX1 and the second pixel PX2 of FIG. 4. Descriptions which are the same as or similar to the above descriptions are omitted.

In FIG. 4, pixels (for example, first and second pixels) PX1 and PX2 of the pixel array 10 may further include a lens layer 300 and color filters (for example, first and second color filters) 201 and 202. The pixels PX1 and PX2 may each include pixel transistors (for example, the reset transistor RX, the transmission transistor TX, the driving transistor DX, and the selection transistor SX of FIG. 2) and a floating diffusion region FD.

The pixels PX1 and PX2 may include a semiconductor substrate 100. The semiconductor substrate 100 may include a first surface suf1. The first surface suf1 may be referred to as a back side of the semiconductor substrate 100. The semiconductor substrate 100 may include a second surface suf2 opposite to the first surface suf1. The second surface suf2 may be referred to as a front side. A wiring layer may be disposed on the second surface suf2 of the semiconductor substrate 100, and a light transmitting layer may be disposed on the first surface suf1. The light transmitting layer may include, for example, the color filters 201 and 202 and the lens layer 300.

Light may pass through the light transmitting layer of the second surface suf2 and may be incident on a photoelectric conversion device 120. Generally, in an image sensor, a structure where a wiring layer and a light transmitting layer are disposed on opposite surfaces of the semiconductor substrate 100 (for example, a structure where the wiring layer is disposed on the second surface suf2 of the semiconductor substrate 100 and the light transmitting layer is disposed on the first surface suf1) may be referred to as a back side illumination structure. On the other hand, a structure where a wiring layer and a light transmitting layer are disposed on the same surface (for example, the second surface suf2) of the semiconductor substrate 100 may be referred to as a front side illumination structure.

The semiconductor substrate 100 may include the first epitaxial layer 110, a photoelectric conversion device 120, and the second epitaxial layer 130. The first epitaxial layer 110 may contact the photoelectric conversion device 120. The first epitaxial layer 110 may contact the photoelectric conversion device 120 in a direction toward the second surface suf2 from the first surface suf1. That is, the first epitaxial layer 110 may contact the photoelectric conversion device 120 in a first direction Z. The photoelectric conversion device 120 may be formed on the first epitaxial layer 110 by an epitaxial growth process. The photoelectric conversion device 120 may contact the second epitaxial layer 130. The photoelectric conversion device 120 may contact the second epitaxial layer 130 in the first direction Z. The second epitaxial layer 130 may be disposed between the photoelectric conversion device 120 and the second surface suf2.

The color filters 201 and 202 may be disposed on the first surface suf1. The color filters 201 and 202 may be disposed on the first surface suf1 of the semiconductor substrate 100 in a second direction (−) Z opposite to the first direction (+) Z. The color filters 201 and 202 may transmit light of a certain spectrum area. For example, the color filters 201 and 202 may transmit light of red, blue, and green areas.

Colors capable of being sensed by the pixels PX1 and PX2 may be determined based on the color filters 201 and 202 disposed in the pixels PX1 and PX2. The first color filter 201 may be disposed on the first surface suf1 of the first pixel PX1. For example, the first color filter 201 may be a red color filter and may transmit light of the red area. The light of the red area may pass through the first color filter 201 and may be incident on the photoelectric conversion device 120, and the photoelectric conversion device 120 may generate a photocharge from the light of the red area. When the first color filter 201 is a blue color filter, light of the blue area may pass through the first color filter 201 and may be incident on the photoelectric conversion device 120, and the photoelectric conversion device 120 may generate a photocharge from the light of the blue area. When the first color filter 201 is a green color filter, light of the green area may pass through the first color filter 201 and may be incident on the photoelectric conversion device 120, and the photoelectric conversion device 120 may generate a photocharge from the light of the green area. The photoelectric conversion device 120 may generate a photocharge from light which passes through each of the first and second color filters 201 and 202 and is incident on the photoelectric conversion device 120. For example, the photoelectric conversion device 120 may generate a photocharge from the light of the blue area, generate a photocharge from the light of the red area, and generate a photocharge from the light of the green area.

The second color filter 202 may be disposed on the first surface suf1 of the second pixel PX2. For example, the second color filter 202 may be a blue color filter and may transmit the light of the blue area. However, the inventive concept is not limited thereto. The second pixel PX2 may be a pixel adjacent to the first pixel PX1 in an X-axis direction. For example, the color filters 201 and 202 having different colors may be provided in adjacent pixels. The first color filter 201 and the second color filter 202 may be color filters having different colors. However, the inventive concept is not limited thereto. In other embodiments, the color filters 201 and 202 having the same color may be provided in adjacent pixels. For example, the first color filter 201 and the second color filter 202 may be color filters having the same color.

The lens layer 300 may be disposed on the color filters 201 and 202. The lens layer 300 may be disposed on the color filters 201 and 202 in a second direction (−) Z. The lens layer 300 may collect light incident on the pixels PX1 and PX2. The lens layer 300 may be a micro lens.

The pixels PX1 and PX2 may each include the floating diffusion region FD and pixel transistors. For example, the pixel transistors may include the reset transistor RX, the transmission transistor TX, the driving transistor DX, and the selection transistor SX each described above with reference to FIG. 2. The pixel transistors may be formed on the second surface suf2 of the semiconductor substrate 100. For example, the pixel transistors may be connected with a wiring layer, disposed on the second surface suf2, through a contact. In FIG. 4, for convenience, only a transmission gate TG of the transmission transistor TX is illustrated. According to some implementations, the pixels PX1 and PX2 may share at least one of the reset transistor RX, the transmission transistor TX, the driving transistor DX, and the selection transistor SX with the other pixel. For example, the first pixel PX1 and the second pixel PX2 may share the selection transistor SX.

The transmission gate TG may be formed on the second surface suf2. For example, the transmission gate TG may be a vertical transmission gate. In FIG. 4, the transmission gate TG is shown as a recess gate type that extends from the second surface suf2 to the inside of the semiconductor substrate 100. However, in some implementations, the shape of the transmission gate TG is not limited thereto. For example, at least a portion of the transmission gate TG may extend to an inner portion of second epitaxial layer 130. The transmission gate TG may be disposed apart from the photoelectric conversion device 120 and may be disposed to contact the photoelectric conversion device 120.

The floating diffusion region FD may accumulate photocharges generated by the photoelectric conversion device 120. The photocharge generated by the photoelectric conversion device 120 may be transferred to the floating diffusion region FD through the transmission gate TG. The floating diffusion region FD may be formed on the second surface suf2. At least a portion of the floating diffusion region FD may be formed in the second epitaxial layer 130. For example, the floating diffusion region FD may be formed in the second epitaxial layer 130 on the second surface suf2. According to some implementations, one pixel may share the floating diffusion region FD with the other pixel. For example, the floating diffusion region FD of each of the first pixel PX1 and the second pixel PX2 may be shared.

A wiring layer may be disposed on the second surface suf2 of the semiconductor substrate 100. The wiring layer may be electrically connected with the pixel transistors. According to some implementations, the wiring layer may be formed in a stack structure of a plurality of layers.

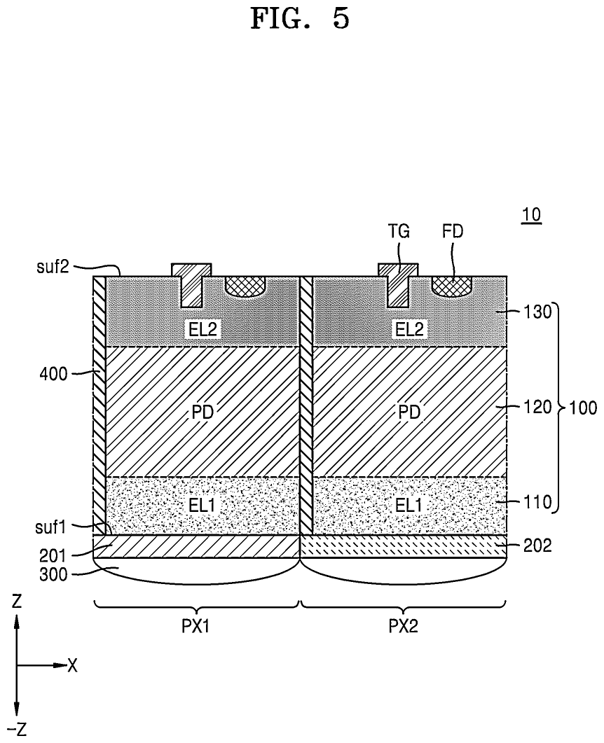

FIG. 5 is a diagram of an example of a device isolation layer according to some implementations. Compared to FIG. 4, each of pixels (for example, first and second pixels) PX1 and PX2 may further include a device isolation layer 400. Descriptions that are the same as or similar to the above descriptions may be omitted.

Each of the pixels PX1 and PX2 may include the device isolation layer 400. The device isolation layer 400 may divide at least some of a plurality of pixels included in a pixel array 10. The device isolation layer 400 may be disposed in a semiconductor substrate 100 and may divide each of the plurality of pixels. The first pixel PX1 and the second pixel PX2 may be divided by the device isolation layer 400.

The device isolation layer 400 may prevent photocharges, generated from light incident on the pixels PX1 and PX2, from being transferred to adjacent pixels PX1 and PX2. For example, the device isolation layer 400 may prevent crosstalk between adjacent pixels. In some implementations, the device isolation layer 400 may pass through the semiconductor substrate 100. The device isolation layer 400 may extend from the second surface suf2 to the first surface suf1. In some implementations, the device isolation layer 400 may be disposed to pass through the second epitaxial layer 130, the photoelectric conversion device 120, and the first epitaxial layer 110.

A deep trench may be formed in the semiconductor substrate 100, and the device isolation layer 400 may be formed by filling an insulating material and a conductive material in the trench. The device isolation layer 400 may be referred to as a deep trench isolation (DTI) structure. Furthermore, the device isolation layer 400 may be classified into a front DTI or a back DTI based on whether the trench is formed in the front side or back side of the semiconductor substrate 100.

The device isolation layer 400 may have various shapes depending on the shape of the trench. In FIG. 5, the device isolation layer 400 is shown having a rectangular shape, but it is not limited thereto. An image sensor may decrease crosstalk between the pixels PX1 and PX2 to reduce noise. Accordingly, the image sensor may obtain an image having enhanced image quality.

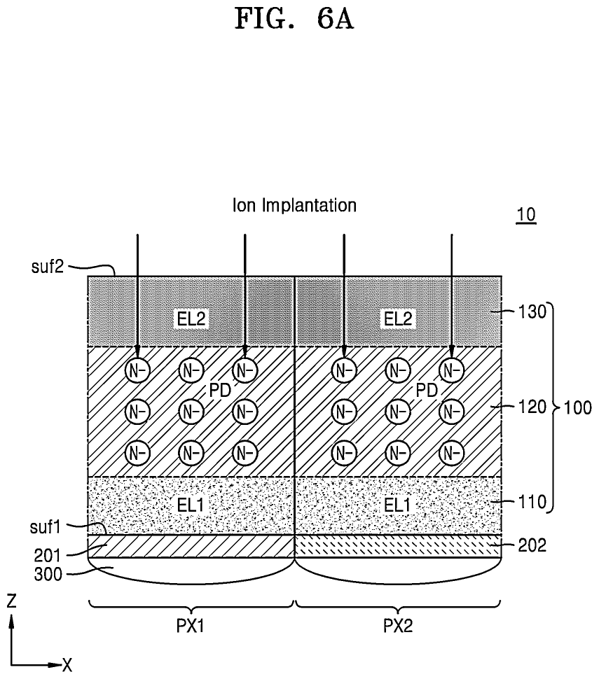

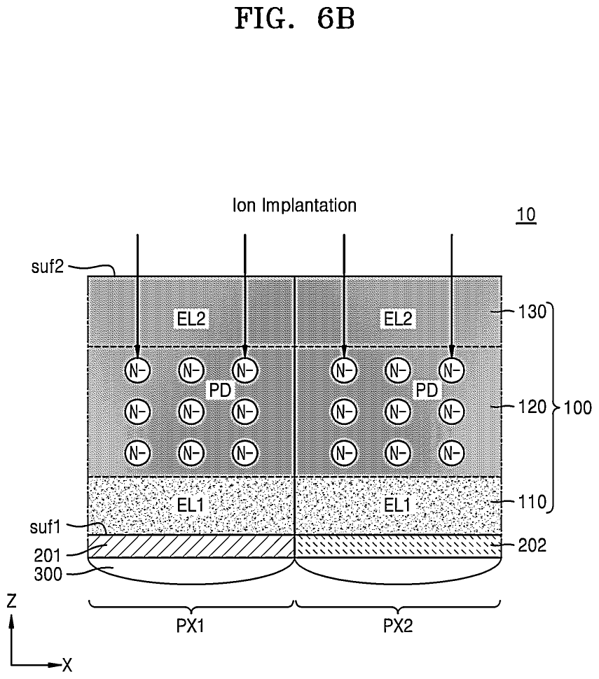

FIG. 6A is a cross-sectional view of an example of a pixel for describing a method of implanting impurities into a photoelectric conversion device according to some implementations. In FIG. 6A, a photoelectric conversion device 120 and a second epitaxial layer 130 are formed by an epitaxial growth process with different concentrations may be assumed.

The photoelectric conversion device 120 and the second epitaxial layer 130 may each be an epitaxial layer of the second conductive type. In some implementations, concentrations of the photoelectric conversion device 120 and the second epitaxial layer 130 each formed by an epitaxial growth process may differ. For example, the photoelectric conversion device 120 of the second conductive type may be formed by an epitaxial growth process with a first concentration, and the second epitaxial layer 130 of the second conductive type may be formed with a second concentration.

Impurities of the same conductive type as a conductive type formed by an epitaxial growth process may be further implanted into the photoelectric conversion device 120. Impurities of the second conductive type may be further implanted into the photoelectric conversion device 120 by an ion implantation process. For example, N-type impurities may be further implanted into the photoelectric conversion device 120 which is an N-type epitaxial layer, based on an ion implantation process. Because the N-type impurities are further implanted into the photoelectric conversion device 120 which is the N-type epitaxial layer, an impurity concentration of the photoelectric conversion device 120 may be more easily adjusted to a desired concentration. Also, instead of forming the photoelectric conversion device 120 by implanting N-type impurities into a P-type epitaxial layer through an ion implantation process, the N-type impurities may be further implanted into the photoelectric conversion device 120 which is the N-type epitaxial layer, and thus, a small amount of N-type impurities may be implanted into the photoelectric conversion device 120, thereby minimizing a lattice defect and enhancing a photoelectric effect.

FIG. 6B is a cross-sectional view of an example of a pixel for describing a method of implanting impurities into a photoelectric conversion device according to some implementations. In FIG. 6B, a photoelectric conversion device 120 and a second epitaxial layer 130 are formed by an epitaxial growth process with the same concentration may be assumed.

In some implementations, concentrations of the photoelectric conversion device 120 and the second epitaxial layer 130 each formed by an epitaxial growth process may be equal to each other. For example, the photoelectric conversion device 120 and the second epitaxial layer 130 each having the second conductive type may be formed by an epitaxial growth process with the first concentration.

Impurities of the second conductive type may be further implanted into the photoelectric conversion device 120 by an ion implantation process. Because the impurities of the second conductive type are further implanted into the photoelectric conversion device 120, a concentration of impurities of the second conductive type of the photoelectric conversion device 120 may be higher than a concentration of impurities of the second conductive type of the second epitaxial layer 130. Accordingly, the photoelectric conversion device 120 may be doped with N-type impurities having a high concentration.

An N-type impurity concentration difference between the photoelectric conversion device 120 and the second epitaxial layer 130 may occur due to an ion implantation process. The photoelectric conversion device 120 may be doped with N-type impurities having a high concentration and may perform a photoelectric conversion function. Because the impurities of the second conductive type are further implanted into the photoelectric conversion device 120 by an ion implantation process, an N-type impurity difference between the photoelectric conversion device 120 and the second epitaxial layer 130, and the photoelectric conversion device 120 may be differentiated from the second epitaxial layer 130.

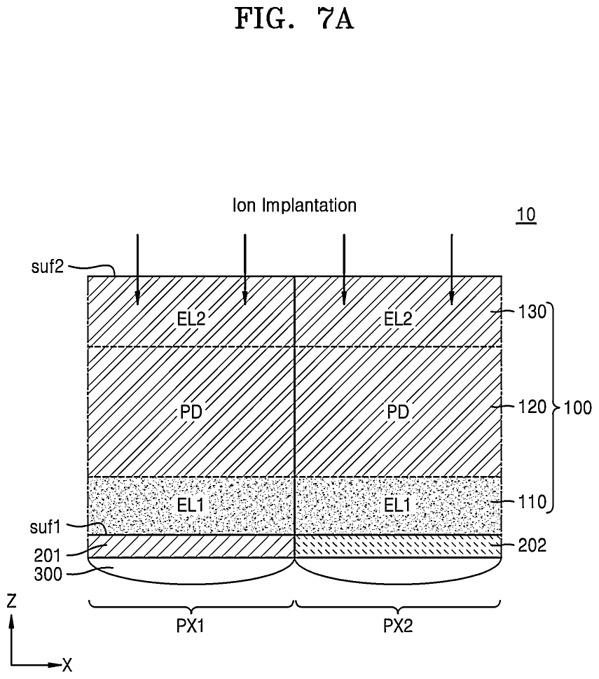

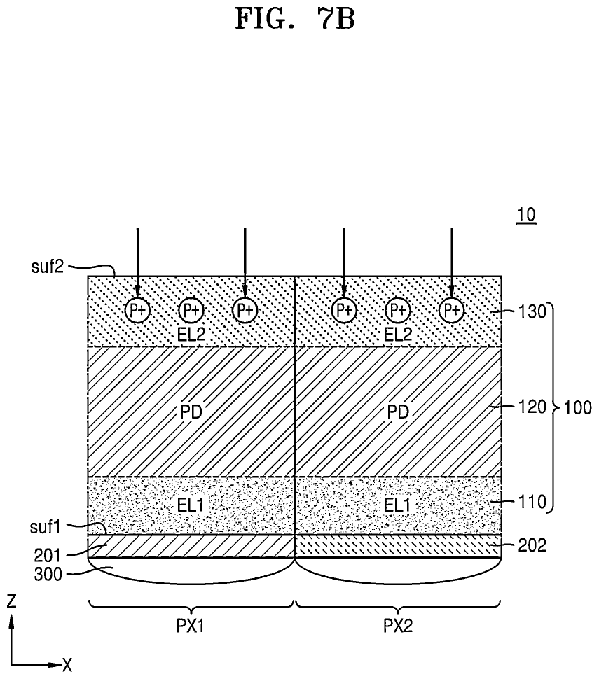

FIG. 7A is a cross-sectional view of an example of a pixel for describing a second epitaxial layer and a photoelectric conversion device according to some implementations. In FIG. 7A, a photoelectric conversion device 120 and a second epitaxial layer 130 are formed by an epitaxial growth process with the same concentration may be assumed.

In some implementations, concentrations of the photoelectric conversion device 120 and the second epitaxial layer 130 each formed by an epitaxial growth process may be equal to each other. The photoelectric conversion device 120 and the second epitaxial layer 130 may be formed by an epitaxial growth process and an ion implantation process to have the second conductive type and the first concentration. When impurities are implanted into the second epitaxial layer 130, concentrations of the photoelectric conversion device 120 and the second epitaxial layer 130 may differ despite that the photoelectric conversion device 120 and the second epitaxial layer 130 are formed by an epitaxial growth process with the same concentration. Hereinafter, a second epitaxial layer 130 into which impurities are implanted will be described with reference to FIG. 7B.

FIG. 7B is a cross-sectional view of an example of a pixel illustrating a second epitaxial layer into which impurities are implanted according to some implementations. In FIG. 7B, impurities of the first conductive type may be further implanted into the photoelectric conversion device 120 by an ion implantation process. Impurities of a conductive type that differs from a conductive type formed by an epitaxial growth process may be implanted by an epitaxial growth process. For example, P-type impurities may be implanted into an N-type second epitaxial layer 130 by an ion implantation process. Because the P-type impurities are further implanted into the second epitaxial layer 130, a concentration of N-type impurities of the photoelectric conversion device 120 may be higher than a concentration of N-type impurities of the second epitaxial layer 130.

Because the P-type impurities are implanted into the second epitaxial layer 130, an N-type impurity concentration difference between the photoelectric conversion device 120 and the second epitaxial layer 130 may occur. The N-type second epitaxial layer 130 may be doped with P-type impurities by an ion implantation process, and a barrier with the photoelectric conversion device 120 may be formed.

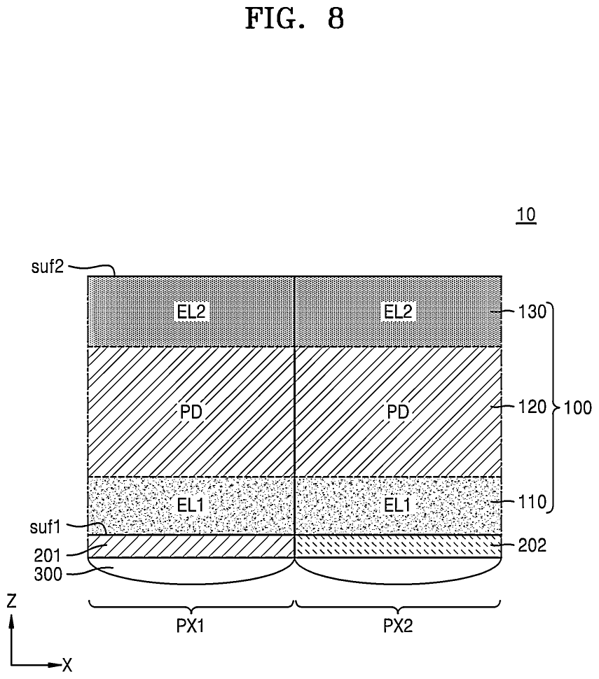

FIG. 8 is a cross-sectional view of an example of a pixel illustrating a second epitaxial layer having a first conductive type according to some implementations. In FIG. 8, a second epitaxial layer 130 may be formed as a conductive type which differs from that of a photoelectric conversion device 120. The second epitaxial layer 130 may be formed as an epitaxial layer of the first conductive type by using an epitaxial growth process. For example, the first epitaxial layer 110 may be a P-type epitaxial layer, the photoelectric conversion device 120 may be an N-type epitaxial layer, and the second epitaxial layer 130 may be a P-type epitaxial layer. The P-type second epitaxial layer 130 may be formed on the photoelectric conversion device 120.

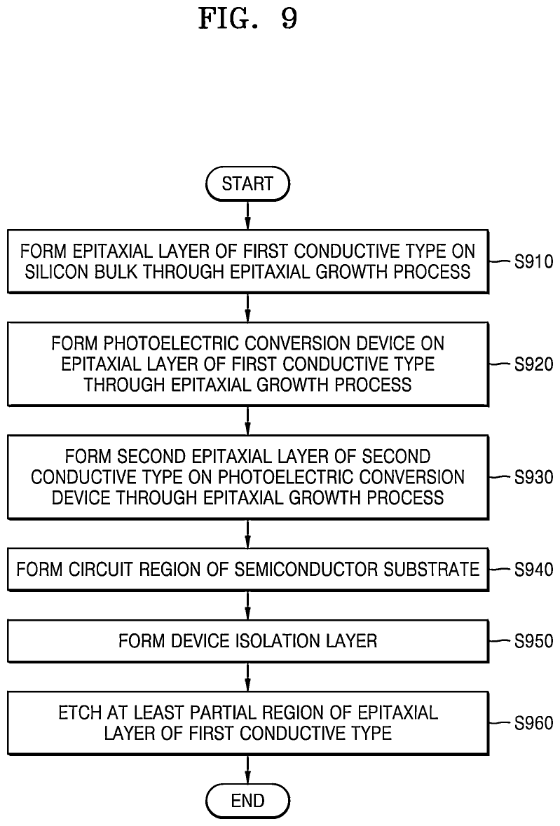

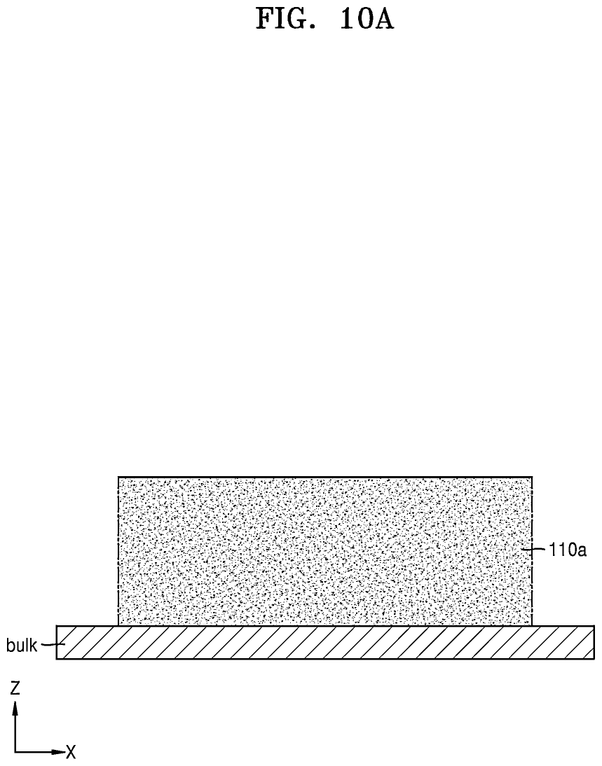

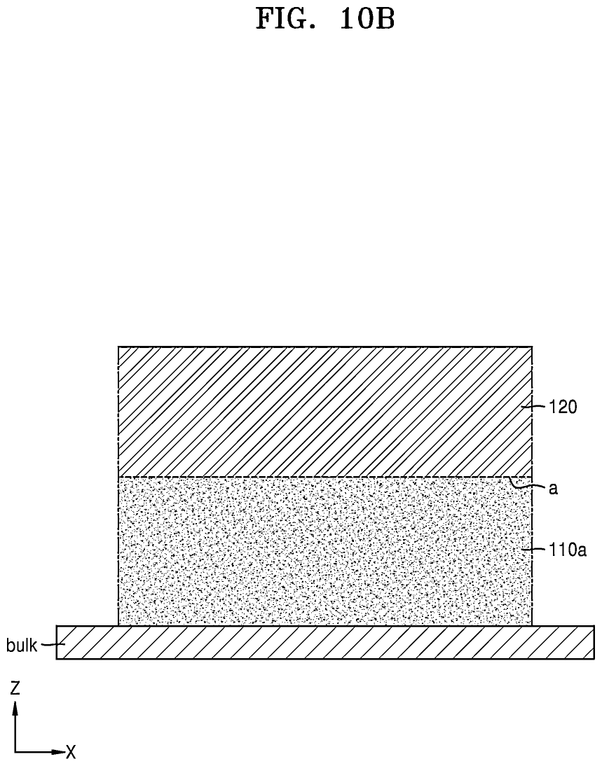

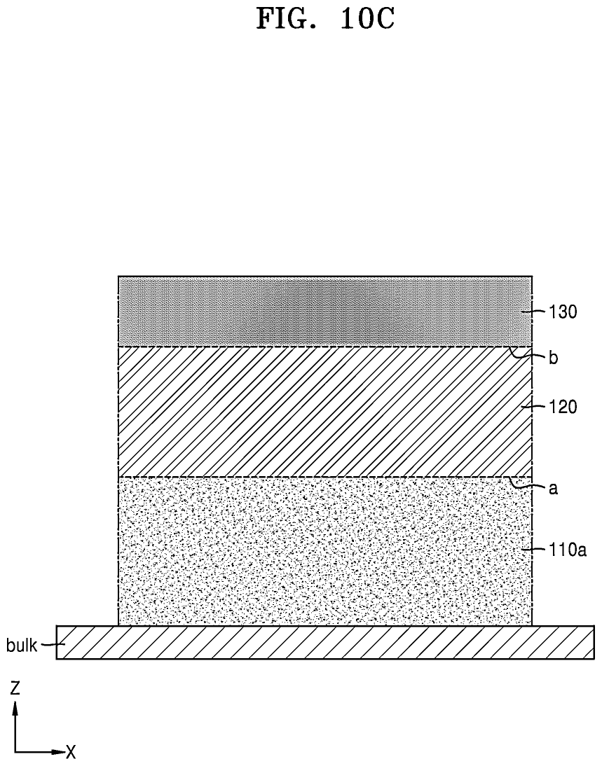

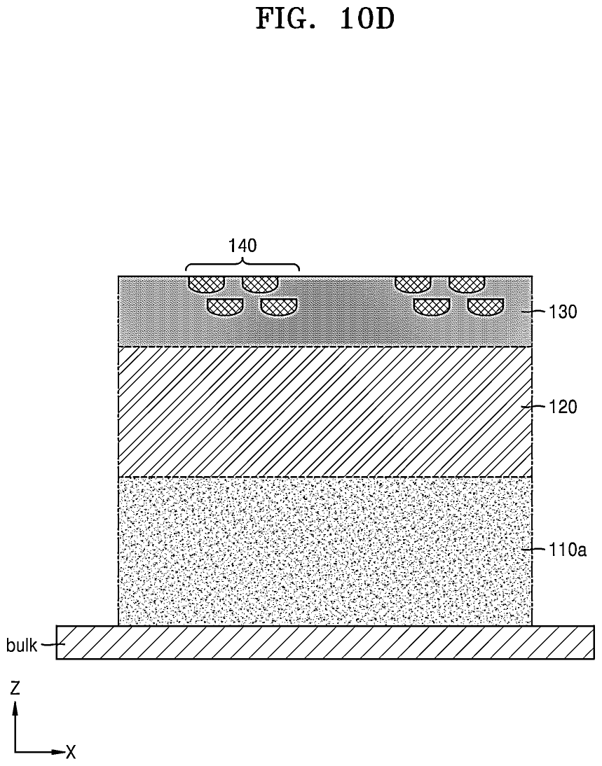

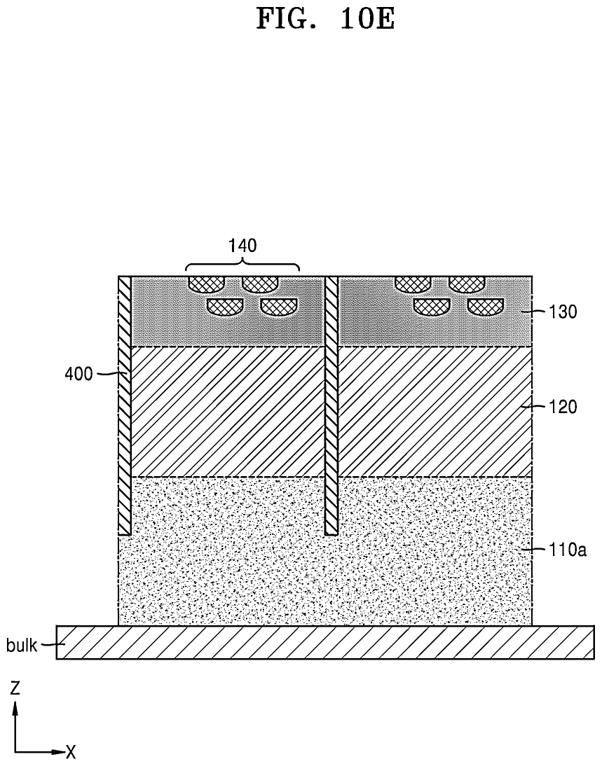

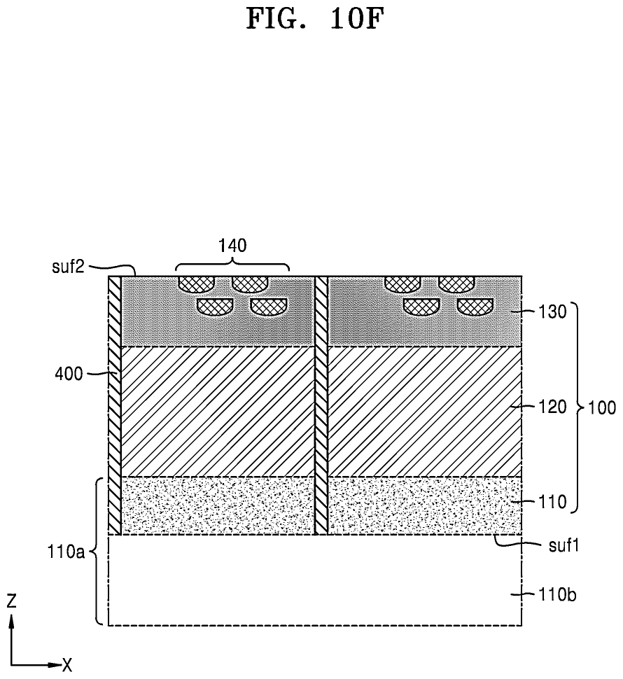

FIG. 9 is a flowchart describing an example of a method of manufacturing an image sensor according to some implementations. FIGS. 10A to 10F are cross-sectional views of an example of a pixel for describing a method of manufacturing an image sensor according to some implementations. Descriptions which are the same as or similar to the above descriptions may be omitted.

In FIGS. 9 and 10A, a method of manufacturing an image sensor (for example, the image sensor 1 of FIG. 1) may include operation S910 of forming an epitaxial layer 110a of the first conductive type on a silicon bulk through an epitaxial growth process. For example, a P-type epitaxial layer 110a may be formed on the silicon bulk by an epitaxial growth process. The epitaxial layer 110a may epitaxial-grow in a first direction (+) Z on the silicon bulk.

In FIGS. 9 and 10B, the method of manufacturing an image sensor may include operation S920 of forming a photoelectric conversion device 120 of the second conductive type. The photoelectric conversion device 120 may be formed on the first epitaxial layer 110a of the first conductive type by an epitaxial growth process.

The epitaxial layer 110a may include a surface a opposite to a surface contacting the silicon bulk. An epitaxial layer of the second conductive type may grow on the first epitaxial layer 110a of the first conductive type, and the photoelectric conversion device 120 may be formed. The photoelectric conversion device 120 may be formed in the first direction (+) Z from the surface a. The photoelectric conversion device 120 may be formed as the second conductive type to have the first concentration by using an epitaxial growth process. For example, the photoelectric conversion device 120 may be an N-type epitaxial layer.

In FIGS. 9 and 10C, the method of manufacturing an image sensor may include operation S930 of forming a second epitaxial layer 130. The second epitaxial layer 130 may be formed on the photoelectric conversion device 120 by an epitaxial growth process.

The photoelectric conversion device 120 may include a surface b opposite to the surface a. The second epitaxial layer 130 may be formed on the photoelectric conversion device 120 of the second conductive type by an epitaxial growth process. The second epitaxial layer 130 may be formed in the first direction (+) Z from the surface b. For example, the second epitaxial layer 130 may be an N-type epitaxial layer.

The second epitaxial layer 130 may be formed to have the second concentration through an epitaxial growth process. For example, an N-type impurity concentration of the photoelectric conversion device 120 formed by an epitaxial growth process may differ from an N-type impurity concentration of the second epitaxial layer 130 formed by an epitaxial growth process. That is, the first concentration may differ from the second concentration. For example, the first concentration may be a high concentration which is higher than the second concentration.

In FIGS. 9 and 10D, the method of manufacturing an image sensor may include operation S940 of forming a circuit region 140. The circuit region 140 may be formed in a semiconductor substrate. The semiconductor substrate may include at least a partial region of the epitaxial layer 110a, the photoelectric conversion device 120, and the second epitaxial layer 130. The circuit region 140 may include pixel transistors (for example, the reset transistor RX, the transmission transistor TX, the driving transistor DX, and the selection transistor SX of FIG. 2) and a floating diffusion region. A transmission gate and the floating diffusion region may be formed on a second surface suf2 (in FIG. 8) of the semiconductor substrate. For example, at least a partial region of the transmission gate and at least a partial region of the floating diffusion region may be formed in the second epitaxial layer 130.

In FIGS. 9 and 10E, the method of manufacturing an image sensor may include operation S950 of forming a device isolation layer 400. Device isolation layers 400 may be formed by selectively etching the semiconductor substrate. The device isolation layers 400 may be formed in a second direction (−) Z at the second surface suf2 of the semiconductor substrate. For example, the device isolation layer 400 may be formed by a photolithography etching process.

The device isolation layers 400 may be formed apart from one another in an X-axis direction. The device isolation layers 400 may be formed apart from one another by a certain interval. The device isolation layer 400 may be formed to pass through at least a portion of the semiconductor substrate. The device isolation layer 400 may be etched from the second surface suf2 to an inner portion of the semiconductor substrate. In some implementations, the device isolation layer 400 may be formed to pass through at least a portion of the epitaxial layer 110a, the second epitaxial layer 130, and the photoelectric conversion device 120.

In FIGS. 9 and 10F, the method of manufacturing an image sensor may include operation S960 of etching at least a partial region 110b of the epitaxial layer 110a of the first conductive type. After the device isolation layers 400 are formed, the at least partial region 110b of the epitaxial layer 110a may be etched depending on the case.

For example, the at least partial region 110b of the epitaxial layer 110a may be etched, and a first epitaxial layer 110 may be formed. The first epitaxial layer 110 may be an epitaxial layer of the first conductive type (for example, P type). The first epitaxial layer 110, the photoelectric conversion device 120, and the second epitaxial layer 130 may configure the semiconductor substrate 100. The semiconductor substrate 100 may include a second surface suf2 (in FIG. 8) and a first surface suf1 (in FIG. 8) opposite to the second surface suf2.

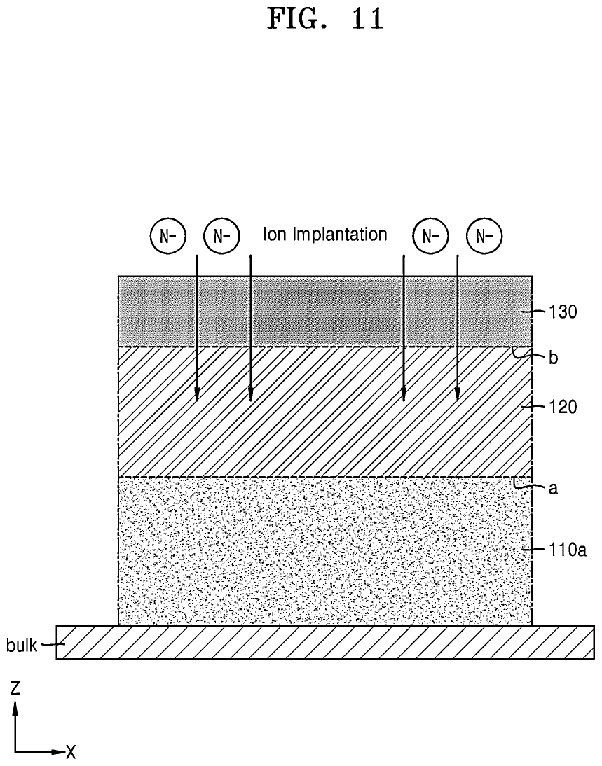

FIG. 11 is a cross-sectional view of an example of a pixel for describing a method of manufacturing an image sensor by using an ion implantation process according to some implementations.

In FIG. 11, the method of manufacturing an image sensor may further include an operation of implanting impurities into a photoelectric conversion device 120 through an ion implantation process. For example, after operation S930 (in FIG. 9), an operation of implanting impurities into the photoelectric conversion device 120 (in FIG. 11) through an ion implantation process may be performed. An epitaxial layer 110a of the first conductive type may be formed on a silicon bulk, the photoelectric conversion device 120 of the second conductive type and a second epitaxial layer 130 of the second conductive type may be formed, and impurities may be implanted into the photoelectric conversion device 120. However, in the method of manufacturing an image sensor, the order of an operation of further implanting impurities into the photoelectric conversion device 120 through an ion implantation process is not limited thereto.

Impurities having the same conductive type as that of the photoelectric conversion device 120 formed by an epitaxial growth process may be further implanted into the photoelectric conversion device 120. Impurities of the second conductive type may be further implanted into the photoelectric conversion device 120 by an ion implantation process. For example, N-type impurities may be further implanted into the photoelectric conversion device 120 which is an N-type epitaxial layer, based on an ion implantation process. Because the N-type impurities are further implanted into the photoelectric conversion device 120 which is the N-type epitaxial layer, an impurity concentration of the photoelectric conversion device 120 may be more easily adjusted to a desired concentration.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the subject matter of the present disclosure has been particularly shown and described with reference to different implementations, it will be understood that various changes in form and details may be made without departing from the spirit and scope of the following claims.

What is claimed is:

1. An image sensor including a plurality of pixels, each pixel of the plurality of pixels comprising:
a first epitaxial layer of a first conductive charge carrier type disposed on a first surface of a semiconductor substrate;
a photoelectric conversion device disposed on the first epitaxial layer, the photoelectric conversion device having a second conductive type that differs from the first conductive type; and
a second epitaxial layer of a second conductive charge carrier type disposed between the photoelectric conversion device and a second surface of the semiconductor substrate,
wherein the photoelectric conversion device comprises an additional epitaxial layer of the second conductive type.

2. The image sensor of claim 1,
wherein the additional epitaxial layer of the photoelectric conversion device comprises a first charge carrier concentration of the second conductive type,
wherein the second epitaxial layer comprises a second charge carrier concentration of the second conductive type, and
wherein the first charge carrier concentration differs from the second charge carrier concentration.

3. The image sensor of claim 2, wherein the first charge carrier concentration is higher than the second charge carrier concentration.

4. The image sensor of claim 1, wherein the second conductive type of the additional epitaxial layer of the photoelectric conversion device comprises ion implanted charge carriers.

5. The image sensor of claim 1, wherein the second charge carrier type of the second epitaxial layer comprises ion implanted charge carriers.

6. The image sensor of claim 5, wherein the charge carrier concentration of the second conductive type in the second epitaxial layer is the same as the charge carrier concentration of the second conductive type in the additional epitaxial layer.

7. The image sensor of claim 1,
wherein the first conductive type is P type, and
the second conductive type is N type.

8. The image sensor of claim 1,
wherein the first epitaxial layer contacts the photoelectric conversion device in a direction toward the second surface of the semiconductor substrate from the first surface of the semiconductor substrate, and
wherein the photoelectric conversion device contacts the second epitaxial layer in a direction toward the second surface of the semiconductor substrate from the first surface of the semiconductor substrate.

9. The image sensor of claim 1, further comprising a device isolation layer dividing at least some of the plurality of pixels in the semiconductor substrate.

10. The image sensor of claim 9, wherein the device isolation layer passes through the second epitaxial layer, the photoelectric conversion device, and the first epitaxial layer.

11. The image sensor of claim 1, wherein a size of the first epitaxial layer is less than a size of the photoelectric conversion device.

12. A pixel comprising:
a semiconductor substrate including a first surface and a second surface;
a vertical transmission gate formed on the second surface of the semiconductor substrate;
a floating diffusion region configured to accumulate photo-charge generated from the semiconductor substrate through the vertical transmission gate;
a first epitaxial layer having a first conductive type disposed on the first surface of the semiconductor substrate;
a photoelectric conversion device, wherein the photoelectric conversion device comprises an additional epitaxial layer of a second conductive type that differs from the first conductive type, the additional epitaxial layer contacting the first epitaxial layer; and
a second epitaxial layer having the second conductive type, the second epitaxial layer contacting the photoelectric conversion device in a direction toward the second surface of the semiconductor substrate from the first surface of the semiconductor substrate.

13. The pixel of claim 12, wherein the second conductive type of photoelectric conversion device comprises ion implanted charge carriers.

14. The pixel of claim 12, wherein a concentration of the second conductive type of the photoelectric conversion device is higher than a concentration of the second conductive type of the second epitaxial layer.

15. The pixel of claim 12,
wherein a concentration of the second conductive type of the photoelectric conversion device is equal to a concentration of the second conductive type of the second epitaxial layer, and
wherein the second epitaxial layer further comprises ion implanted charge carriers of the first conductive type.

16. The pixel of claim 12, further comprising a device isolation layer disposed on one side surface of the semiconductor substrate,
wherein the device isolation layer extends to the first surface of the semiconductor substrate from the second surface of the semiconductor substrate and passes through the second epitaxial layer, the photoelectric conversion device, and the first epitaxial layer.

17. The pixel of claim 12, wherein at least a portion of the vertical transmission gate and at least a portion of the floating diffusion region are formed in the second epitaxial layer.

18. An image sensor comprising:
a color filter disposed on a first surface of a semiconductor substrate in a second direction opposite to a first direction toward a second surface of the semiconductor substrate from the first surface of the semiconductor substrate;
a lens layer disposed on the color filter in the second direction;
a first epitaxial layer disposed between the first surface and the second surface of the semiconductor substrate and arranged in the first direction on the first surface of the semiconductor substrate, wherein the first epitaxial layer has a first conductive type;
a photoelectric conversion device disposed on the first epitaxial layer in the first direction, wherein the photoelectric conversion device includes an additional epitaxial layer having a second conductive type; and
a second epitaxial layer disposed between the first surface and the second surface of the semiconductor substrate and arranged in the second direction on the second surface of the semiconductor substrate, wherein the second epitaxial layer has a third conductive type.

19. The image sensor of claim 18,
wherein the first conductive type differs from the second conductive type, and
wherein the second conductive type is the same as the third conductive type.

20. The image sensor of claim 18,
wherein the first conductive type differs from the second conductive type, and
wherein the third conductive type is the same as the first conductive type.
